(19) United States
(12) Patent Application Publication
(10) Pub. No.: US 2016/0064365 A1
(43) Pub. Date: Mar. 3, 2016

(54) SEMICONDUCTOR PACKAGE

(71) Applicant: SAMSUNG ELECTRONICS CO., LTD., Suwon-Si (KR)

(72) Inventors: JAE-GWON JANG, Hwaseong-Si (KR); Seok-Hyun Lee, Hwaseong-Si (KR); Ae-Nee Jang, Seoul (KR)

(21) Appl. No.: 14/626,326

(22) Filed: Feb. 19, 2015

(30) Foreign Application Priority Data
Aug. 28, 2014 (KR) 10-2014-0113472

(51) Int. Cl. H01L 25/18; H01L 23/31; H01L 23/498; H01L 25/065; H01L 23/00

(52) U.S. Cl. CPC H01L 25/18; H01L 25/0657; H01L 24/49; H01L 23/49838; H01L 23/3107; H01L 2225/06562; H01L 2225/06506; H01L 2225/0651; H01L 2224/48106; H01L 2224/48145; H01L 2224/48227; H01L 2924/1434; H01L 2224/49107

(57) ABSTRACT

A semiconductor package includes a package substrate having a lower substrate and an upper substrate disposed on the lower substrate, the package substrate having a first cavity, a first semiconductor chip disposed in the first cavity, and a chip stack disposed to partially cover the first cavity on the upper substrate.

### CROSS-REFERENCE TO RELATED APPLICATION

The present application claims under 35 U.S.C. §119 priority to and the benefit of Korean Patent Application No. 10-2014-0113472 filed on Aug. 28, 2014, the entire disclosure of which is incorporated by reference herein.

### BACKGROUND

1. Technical Field

The present disclosure relates to a semiconductor package and a method of fabricating the same.

2. Discussion of Related Art

Recently, the capacity of a flash memory used as a data storage device of a small electronic product, such as a smart phone and a tablet PC, has been rapidly increasing, and the capacity of a solid state drive (SSD) replacing a hard disk drive (HDD) has been also rapidly increasing. As the increase of the data storage capacity progresses, high speed input/output processing of data also progresses. In order to satisfy the requirements for a large capacity and high speed input/output processing of data at the same time, an additional controller chip is typically added. However, since the controller chip is usually added to the inside of a semiconductor package having a limited size, the number of stacks of memory chips therein may be restricted, and, accordingly, it may be difficult to implement a data storage device having a large capacity.

### SUMMARY

Exemplary embodiments of the inventive concepts provide semiconductor packages which satisfy requirements for a large data storage capacity and high speed processing of data input/output at the same time while having a small size.

Exemplary embodiments of the inventive concepts provide a method of fabricating the semiconductor packages.

Exemplary embodiments of the inventive concepts provide electronic apparatuses including the semiconductor package.

The technical objectives of the inventive concepts are not limited to the above objective. Other objectives may become apparent to those of ordinary skill in the art based upon the following descriptions.

In accordance with exemplary embodiments of the inventive concepts, a semiconductor package may include a package substrate including a lower substrate and an upper substrate disposed on the lower substrate and having a first cavity, a first semiconductor chip disposed in the first cavity, and a chip stack disposed on the upper substrate. The chip stack may partially overlie the first cavity.

In accordance with exemplary embodiments of the inventive concepts, a semiconductor package may include a package substrate including a lower substrate and an upper substrate disposed on the lower substrate and having a first cavity and a second cavity, a first semiconductor chip disposed in the first cavity, and a second semiconductor chip disposed in the second cavity, and a chip stack disposed on the upper substrate. The chip stack may overlie the first and second cavities.

In accordance with exemplary embodiments of the inventive concepts, a semiconductor package may include a package substrate including a first cavity, a first semiconductor chip disposed in the first cavity, and a chip stack disposed on the package substrate. The chip stack may overlie a center portion of the first cavity, and does not overlie an edge portion of the first cavity.

### BRIEF DESCRIPTION OF THE DRAWINGS

FIGS. 1A and 1B are top views schematically illustrating a semiconductor package and a package substrate, respectively, in accordance with exemplary embodiments of the inventive concepts;

FIGS. 2A to 2C are cross-sectional views schematically illustrating the semiconductor package taken along line I-I′ of FIG. 1A;

FIGS. 3A and 3B are top views schematically illustrating a semiconductor package and a package substrate, respectively, in accordance with exemplary embodiments of the inventive concepts;

FIGS. 4A and 4B are cross-sectional views schematically illustrating semiconductor packages taken along line II-II′ of FIG. 3A;

FIGS. 5, 6, 7, 8, 9, 10, 11, 12, 13, 14, 15, 16, 17, 18, 19, 20, 21, 22, 23, 24, 25, 26, 27 and 28 are views illustrating methods of fabricating semiconductor packages in accordance with exemplary embodiments of the inventive concepts;

FIG. 29 is a perspective view illustrating an electronic device including at least one of semiconductor packages in accordance with exemplary embodiments of the inventive concepts;

FIG. 30 is a system block diagram illustrating an electronic device including at least one of semiconductor packages in accordance with various exemplary embodiments of the inventive concepts;

FIGS. 31 and 32 are perspective views of electronic devices including at least one of the semiconductor packages in accordance with the exemplary embodiments of the inventive concepts; and

FIG. 33 is a block diagram of an electronic device including at least one of the semiconductor packages in accordance with the exemplary embodiments of the inventive concepts.

### DETAILED DESCRIPTION

Various exemplary embodiments will now be described more fully with reference to the accompanying drawings. The inventive concepts disclosed herein may, however, be embodied in different forms and should not be construed as limited to the exemplary embodiments set forth herein.

The terminology used herein to describe exemplary embodiments of the inventive concepts is not intended to limit the scope of the invention. The use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “connected to” or “coupled to” another element or layer, it can be connected or coupled to the other element or layer or intervening elements or layers may be present. In contrast, when an element is referred to as “directly connected to” or “directly coupled to” another element or layer, there are no intervening elements or layers present. The term “and/or” includes any and all combinations of one or more referents.

Spatially relative terms, such as “beneath,” “below,” “lower,” “above,” “upper,” and the like may be used herein to describe the relationship of one element or feature to another, as illustrated in the drawings. It will be understood that such descriptions are intended to encompass different orientations in use or operation in addition to orientations depicted in the drawings. For example, if a device is turned over, elements described as “below” or “beneath” other elements or features would then be oriented “above” the other elements or features. Thus, the term “below” is intended to mean both above and below, depending upon overall device orientation.

Exemplary embodiments are described herein with reference to a cross-sectional view, a plan view, and/or a block diagram that are schematic illustrations of idealized embodiments and intermediate structures. As such, variations from the shapes of the illustrations as a result, for example, of manufacturing techniques and/or tolerances, are to be expected. Thus, the exemplary embodiments should not be construed as limited to the particular shapes of regions illustrated herein but are to include deviations in shapes that result, for example, from manufacturing. For example, an etched region illustrated as a rectangle will, typically, have rounded or features having a predetermined curvature. Thus, the regions illustrated in the figures are schematic in nature and their shapes are not intended to illustrate the actual shape of a region of a package and are not intended to limit the scope of the inventive concepts.

The same reference numerals denote the same elements throughout the specification. Accordingly, the same numerals and similar numerals can be described with reference to other drawings, even if not specifically described in a corresponding drawing. Further, when a numeral is not marked in a drawing, the numeral can be described with reference to other drawings.

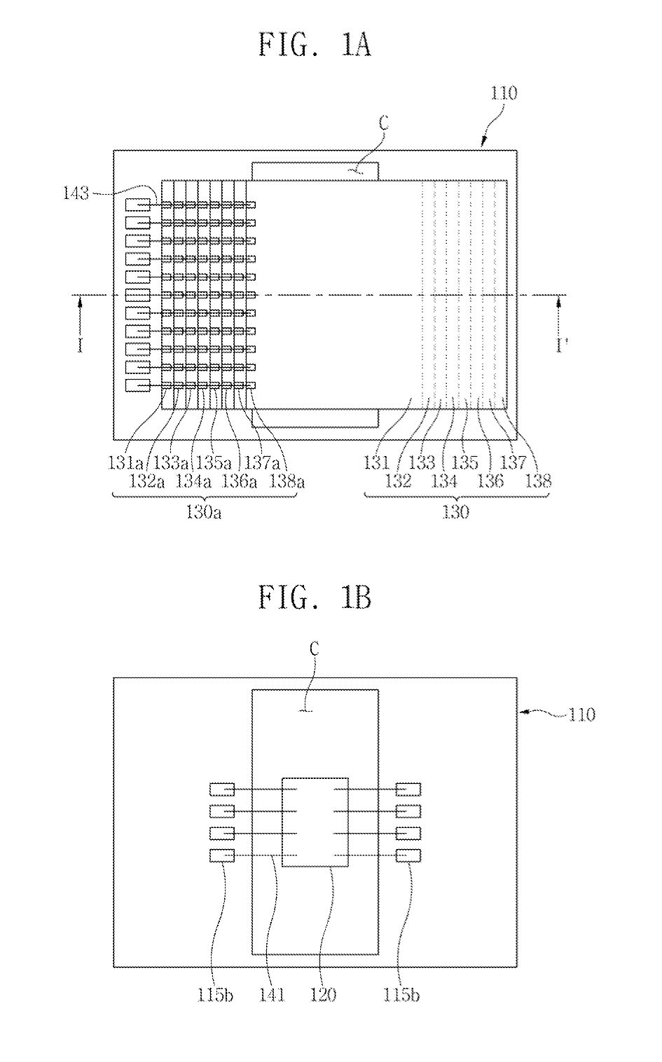

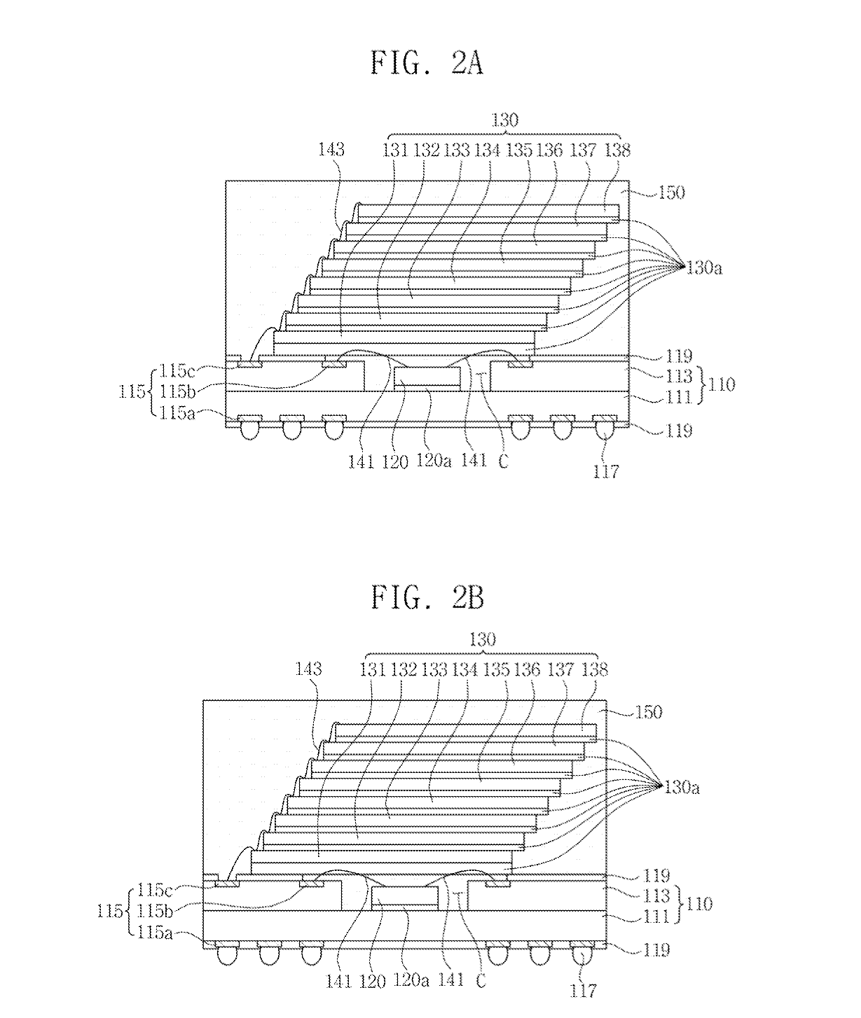

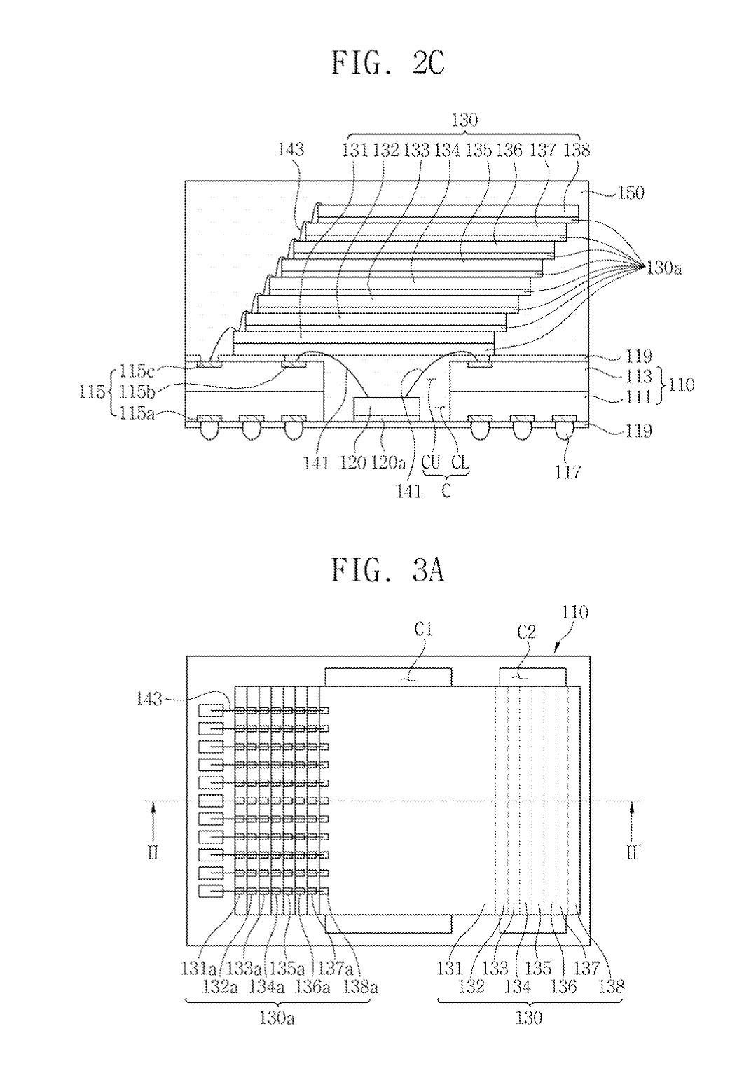

FIGS. 1A and 1B are top views schematically illustrating a semiconductor package and a package substrate, respectively, in accordance with exemplary embodiments of the inventive concepts, and FIGS. 2A, 2B and 2C are vertical cross-sectional views schematically illustrating the semiconductor package taken along line I-I′ of FIG. 1A.

Referring to FIGS. 1A, 1B, and 2A, the semiconductor package in accordance with an exemplary embodiment of the inventive concepts may include a package substrate 110, a controller chip 120, a chip stack 130, and a molding compound 150. The semiconductor package may further include second and third connection pads 115b, 115c formed on an upper surface and first connection pads 115a formed on a lower surface of the package substrate 110. The semiconductor package may further include protection layers 119 formed to expose the second connection pads 115b on the upper surface and the first connection pads 115a on the lower surface of the package substrate 110. The semiconductor package may further include first wires 141 electrically connecting the second connection pads 115b to the controller chip 120, and second wires 143 electrically connecting the third connection pads 115c to the chip stack 130.

The package substrate 110 may include a lower substrate 111 and an upper substrate 113 disposed on the lower substrate 111. The upper substrate 113 may include a cavity C. The cavity C may pass through the upper substrate 113 to expose a surface of the lower substrate 111. In a top view, the cavity C may have the shape of a rectangle elongated in a first direction. For example, the first direction may correspond to a major axis direction of the cavity C. The cavity C may include a portion overlain by the chip stack 130, and a portion not overlain by the chip stack 130. In the top view, the cavity C may include a portion overlapped with the chip stack 130, and a portion not overlapped with the chip stack 130. For example, a center portion of the cavity C may be overlain by the chip stack 130, and both edge portions of the cavity C in the first direction may be exposed without being overlain by the chip stack 130. In the top view, a center portion of the cavity C may be overlapped with the chip stack 130, and both edge portions of the cavity C in the first direction may be exposed without being overlapped with the chip stack 130.

Each of the lower substrate 111 and the upper substrate 113 may include a rigid printed circuit board, a flexible printed circuit board, or a rigid-flexible printed circuit board. For example, in the exemplary embodiment, each of the lower substrate 111 and the upper substrate 113 may include a pre-preg.

The first connection pads 15a may be formed on a lower surface of the lower substrate 111 and second and third connection pads 115b, 115c may be formed on an upper surface of the upper substrate 113. The connection pads 115a, 115b, 115c each may include a metal material such as copper (Cu), nickel (Ni), or aluminum (Al).

In some exemplary embodiments, each of the first connection pads 115a, the second connection pads 115b, and the third connection pads 115c may be buried in the package substrate 110. That is, the first connection pads 115a may be buried in the lower substrate 111 adjacent to the lower surface of the lower substrate 111, and the second connection pads 115b and the third connection pads 115c may be buried in the upper substrate 113 adjacent to the upper surface of the upper substrate 113. Accordingly, each lower surface of the first connection pads 115a may be coplanar with the lower surface of the lower substrate 111. In addition, each upper surface of the second connection pads 115b and the third connection pads 115c may be coplanar with the upper surface of the upper substrate 113.

External connection terminals 117 may be formed on the first connection pads 115a. The external connection terminals 117 may include a solder ball, a solder bump, a pin grid array, a lead grid array, a conductive tab, or a combination thereof. The second connection pads 115b and the third connection pads 115c may be electrically connected to the controller chip 120 and the chip stack 130, respectively. The first connection pads 115a, the second connection pads 115b, and the third connection pads 115c may be electrically connected to each other.

The protection layer 119 may be formed on each of the upper surface and the lower surface of the package substrate 110. For example, the protection layer 119 may be formed on the lower surface of the lower substrate 111 and the upper surface of the upper substrate 113 to expose the first connection pads 115a, the second connection pads 115b, the third connection pads 115c, and the cavity C. The protection layer 119 may include photosensitive soldering resist (PSR).

The controller chip 120 may be a controller or microprocessor including a logic device. The controller chip 120 may be disposed in the cavity C. That is, the controller chip 120 may be disposed on an upper surface of the lower substrate 111 exposed in the cavity C. An upper surface of the controller chip 120 may be located at a lower level than the upper surface of the upper substrate 113. The controller chip 120 may be electrically connected to second connection pads 115b formed on the upper surface of the upper substrate 113 using the first wires 141. A first adhesive layer 120a may be formed between the upper surface of the lower substrate 111 and a lower surface of the controller chip 120. The first adhesive layer 120a may include a non-conductive material such as a die attach film (DAF).

The chip stack 130 may be mounted on the upper substrate 113 of the package substrate 110 to overlie the controller chip 120 and the cavity C. Accordingly, the controller chip 120 may be covered by the chip stack 130. The chip stack 130 may include a plurality of memory chips 131, 132, 133, 134, 135, 136, 137, 138. Each of the plurality of memory chips 131, 132, 133, 134, 135, 136, 137, 138 may include a non-volatile memory device such as a NAND flash memory.

The plurality of memory chips 131, 132, 133, 134, 135, 136, 137, 138 may include bonding pads 131a, 132a, 133a, 134a, 135a, 136a, 137a, 138a, respectively. The bonding pads 131a, 132a, 133a, 134a, 135a, 136a, 137a, 138a may be data input/output pads. The plurality of memory chips 131, 132, 133, 134, 135, 136, 137, 138 may be stacked in a cascade structure. Each of the plurality of memory chips 131, 132, 133, 134, 135, 136, 137, 138 may have a width greater than the controller chip 120. In addition, each of the plurality of memory chips 131, 132, 133, 134, 135, 136, 137, 138 may have a width greater than the cavity C.

Each of the plurality of memory chips 131, 132, 133, 134, 135, 136, 137, 138 may be electrically connected to the third connection pads 115c formed on the upper surface of the upper substrate 113 by the second wires 143.

Second adhesive layers 130a may be disposed between the lowermost memory chip 131 of the plurality of memory chips 131, 132, 133, 134, 135, 136, 137, 138 and the upper substrate 113, and between the plurality of memory chips 131, 132, 133, 134, 135, 136, 137, 138. Each of the second adhesive layers 130a may include a non-conductive adhesive material such as DAF. Among the second adhesive layers 130a, the lowermost second adhesive layer 130a disposed between the lowermost memory chip 131 and the upper substrate 113 may be relatively thicker than the other second adhesive layers 130a. Portions of the first wires 141 may be inserted and buried in the lowermost second adhesive layer 130a.

The first wires 141 and the second wires 143 may electrically connect the second connection pads 115b to the controller chip 120 and the third connection pads 115c to the chip stack 130, respectively. Each of the first wires 141 and the second wires 143 may include a metal material, such as aluminum (Al) or gold (Au).

The molding compound 150 may be formed on the upper substrate 113 to fill the cavity C and cover the chip stack 130. The molding compound 150 may include an epoxy-molding compound (EMC). As described above, since the cavity C includes a portion overlain (or covered) by the chip stack 130 and a portion not overlain (or covered) by the chip stack 130, the molding compound 150 may flow into the portion that is not overlain (or covered) by the chip stack 130 among the cavity C to fill the cavity C, and the controller chip 120 disposed in the cavity C may be fixed by the molding compound 150 filling the cavity C.

So far, the semiconductor package in accordance with the exemplary embodiment of the inventive concepts has been described. Since the semiconductor package in accordance with the exemplary embodiment of the inventive concepts has a controller chip 120 which provides a high speed for data input/output to/from each of the plurality of memory chips 131, 132, 133, 134, 135, 136, 137, 138, and is embedded in package substrate 110, the data input/output speed of each of the plurality of memory chips can be increased and, at the same time, the size of the semiconductor package can be reduced. In addition, as described above, since the controller chip 120 is embedded in the substrate, the number of stacked memory chips can be increased, and thus, a large data storage capacity can be achieved.

Referring to FIGS. 1A, 1B, and 2B, the semiconductor package in accordance with an exemplary embodiment of the inventive concepts may include first connection pads 115a disposed on a lower surface of the lower substrate 111, and second connection pads 115b and third connection pads 115c buried in the upper substrate 113 adjacent to an upper surface of the upper substrate 113. For example, the first connection pads 115a may protrude from the lower surface of the lower substrate 111, and the second connection pads 115b and the third connection pads 115c may be buried in the upper substrate 113 adjacent to the upper surface of the upper substrate 113. Accordingly, lower surfaces of the first connection pads 115a may be located at a lower level than the lower surface of the lower substrate 111. In addition, upper surfaces of the second connection pads 115b and the third connection pads 115c may be coplanar with the upper surface of the upper substrate 113.

Referring to FIGS. 1A, 1B, and 2C, the semiconductor package in accordance with an exemplary embodiment of the inventive concepts may include a cavity C having a lower cavity CL and an upper cavity CU. The lower cavity CL may be formed in the lower substrate 111, and the upper cavity CU may be formed in the upper substrate 113. The lower cavity CL may overlap the upper cavity CU. For example, an inner sidewall of the lower cavity CL may be vertically aligned with an inner sidewall of the upper cavity CU. Accordingly, the package substrate 110 may be fully penetrated by the upper cavity CU and the lower cavity CL. In this way, since the package substrate 110 is fully penetrated by the upper cavity CU and the lower cavity CL, a protection layer 119 formed on the lower surface of the lower substrate 111 may be exposed in the upper cavity CU and the lower cavity CL. The controller chip 120 may be disposed in the lower cavity CL. That is, the controller chip 120 may be disposed on the protection layer 119 exposed in the upper cavity CU and the lower cavity CL.

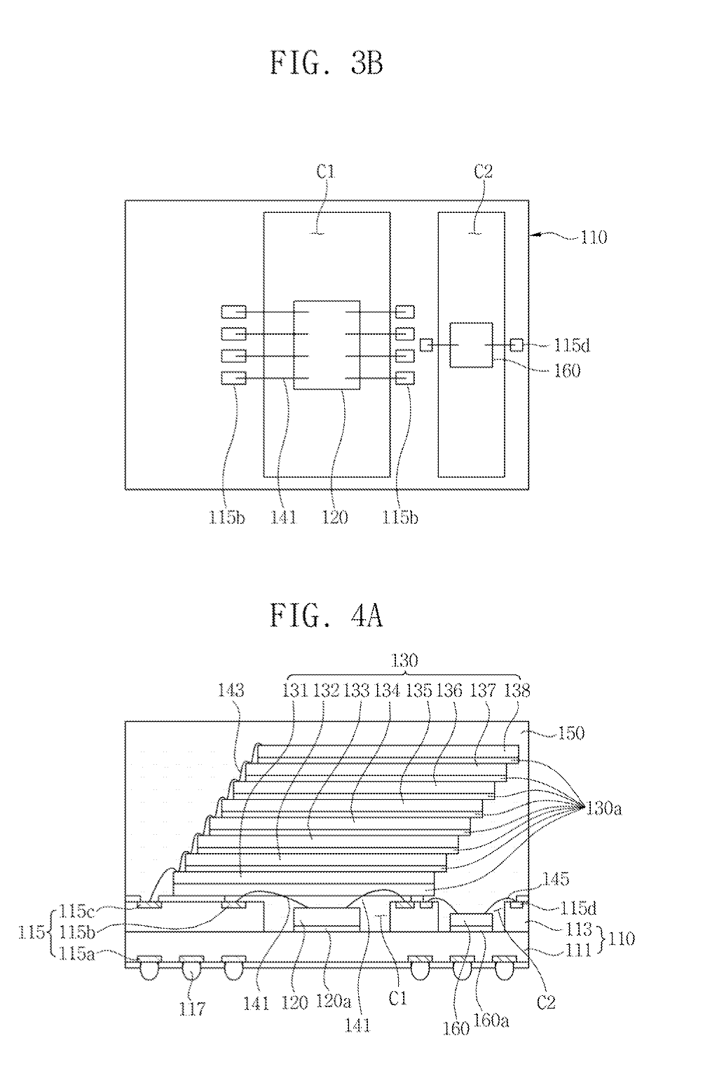

FIGS. 3A and 3B are top views schematically illustrating a semiconductor package and a package substrate, respectively, in accordance with exemplary embodiments of the inventive concepts, and FIGS. 4A and 4B are vertical cross-sectional views schematically illustrating semiconductor packages taken along line II-II′ of FIG. 3A.

Referring to FIGS. 3A, 3B, and 4A, an upper substrate 113 of a semiconductor package in accordance with an exemplary embodiment of the inventive concepts may include a first cavity C1 and a second cavity C2 spaced apart from each other. In the drawings, it is illustrated that two cavities C1, C2 are formed spaced apart from each other in the upper substrate 113, but the number of the cavities are not limited thereto.

The first cavity C1 and the second cavity C2 may have the shape of a rectangle elongated in the same direction. For example, the same direction may correspond to major axis directions of the first and second cavities C1, C2. Each of the first cavity C1 and the second cavity C2 may include a portion overlain by the chip stack 130 and a portion not overlain by the chip stack 130. In a top view, each of the first cavity C1 and the second cavity C2 may include a portion overlapped with the chip stack 130 and a portion not overlapped with the chip stack 130. For example, both edge portions of each of the cavities C1, C2 may be exposed without being overlain by the chip stack 130. That is, in top view, both edge portions of each of the cavities C1, C2 may be exposed without being overlapped with the chip stack 130. The first cavity C1 may be overlain (or covered) by the lowermost memory chip 131 of the chip stack 130, and the second cavity C2 may not be overlain (or covered) by the lowermost memory chip 131 of the chip stack 130. In addition, in the drawings, a length in the major axis of the rectangular first cavity C1 is illustrated as the same as a length in the major axis of the rectangular second cavity C2, but is not limited thereto. The length in the major axis of the first cavity C1 may be different from the length in the major axis of the second cavity C2.

A width of the first cavity C1 may be different from a width of the second cavity C2. For example, the width of the first cavity C1 may be greater than the width of the second cavity C2. For example, the width of the first cavity C1 may correspond to a width in a minor axis of the first cavity C1 crossing the major axis of the first cavity C1. The width of the second cavity C2 may correspond to a width in a minor axis of the second cavity C2 crossing the major axis of the second cavity C2 An upper surface of the lower substrate 111 may be exposed by the first cavity C1 and the second cavity C2.

A controller chip 120 may be disposed on the upper surface of the lower substrate 111 exposed by the first cavity C1. A device 160 may be disposed on the upper surface of the lower substrate 111 exposed by the second cavity C2. The device 160 may be a passive device such as a resistor, a capacitor, and/or an inductor, or the like, or may be a second semiconductor chip. A first adhesive layer 120a may be formed between the controller chip 120 and the upper surface of the lower substrate 111. A third adhesive layer 160a may be formed between the device 160 and the upper surface of the lower substrate 111. The first adhesive layer 120a and the third adhesive layer 160a may include a non-conductive adhesive layer such as DAF.

In addition, fourth connection pads 115d may be further formed on the upper substrate 113 of the package substrate 110. In some exemplary embodiments, the fourth connection pads 115d may be buried in the upper substrate 113 adjacent to the upper surface of the upper substrate 113. The fourth connection pads 115d and the device 160 may be electrically connected by the third wires 145.

In addition, the chip stack 130 disposed on the upper substrate 113 may overlie (or vertically overlap) a portion of the first cavity C1 and a portion of the second cavity C2.

Referring to FIG. 4B, a package substrate 110 of a semiconductor package in accordance with the exemplary embodiment of the inventive concepts, may include a first cavity C1 and a second cavity C2 spaced apart from each other. The first cavity C1 may include a lower cavity CL and an upper cavity CU. The lower cavity CL may be formed in the lower substrate 111, and the upper cavity CU may be formed in the upper substrate 113. The lower cavity CL may be overlapped by the upper cavity CU. For example, an inner sidewall of the lower cavity CL may be aligned with an inner sidewall of the upper cavity CU. The package substrate 110 may be fully penetrated by the upper cavity CU and the lower cavity CL. Since the package substrate 110 is fully penetrated by the upper cavity CU and the lower cavity CL, a protection layer 119 formed on the lower surface of the lower substrate 111 may be exposed. The controller chip 120 may be disposed in the lower cavity CL. For example, the controller chip 120 may be adhered to the protection layer 119 by first adhesive layer 120a and exposed by the upper cavity CU and the lower cavity CL.

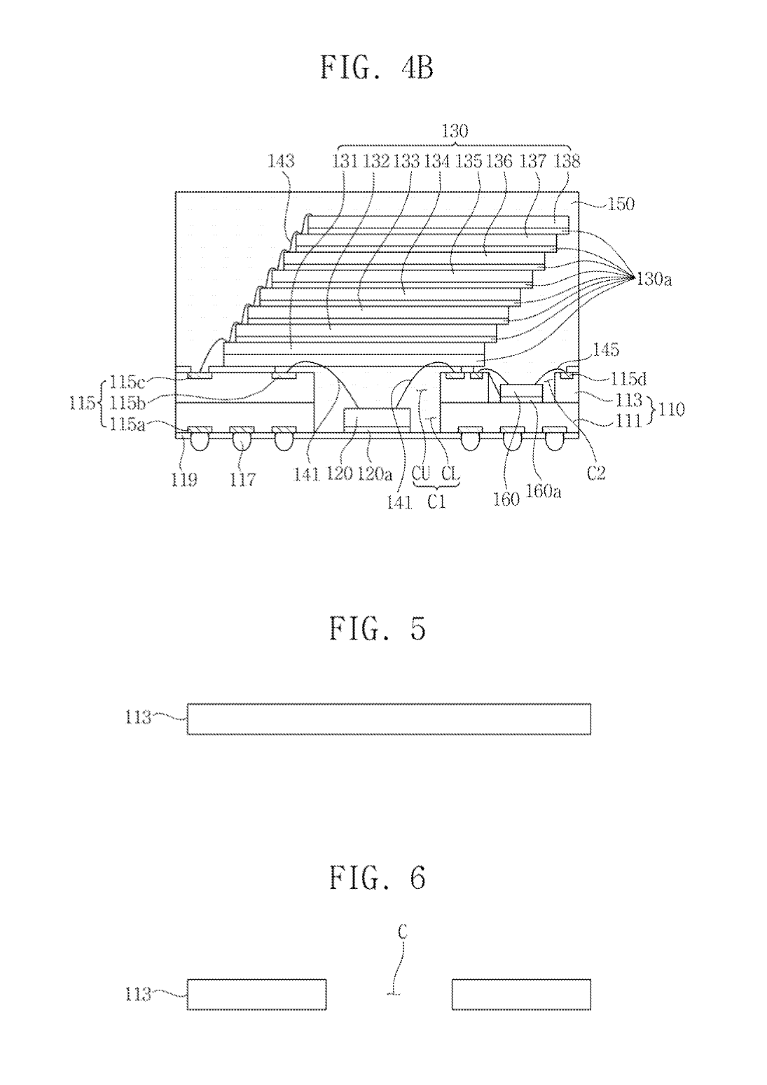

FIGS. 5 to 13 are views illustrating a method of fabricating a semiconductor package in accordance with an exemplary embodiment of the inventive concepts.

Referring to FIG. 5, the method of fabricating a semiconductor package in accordance with an exemplary embodiment of the inventive concepts may include preparing an upper substrate 113. The upper substrate 113 may include a pre-preg.

Referring to FIG. 6, the method may include forming a cavity C by cutting a portion of the upper substrate 113. The cutting may include performing at least one of a die-cutting process, a laser cutting process, and a drilling process. The cavity C may be understood with reference to FIG. 1B or 3B.

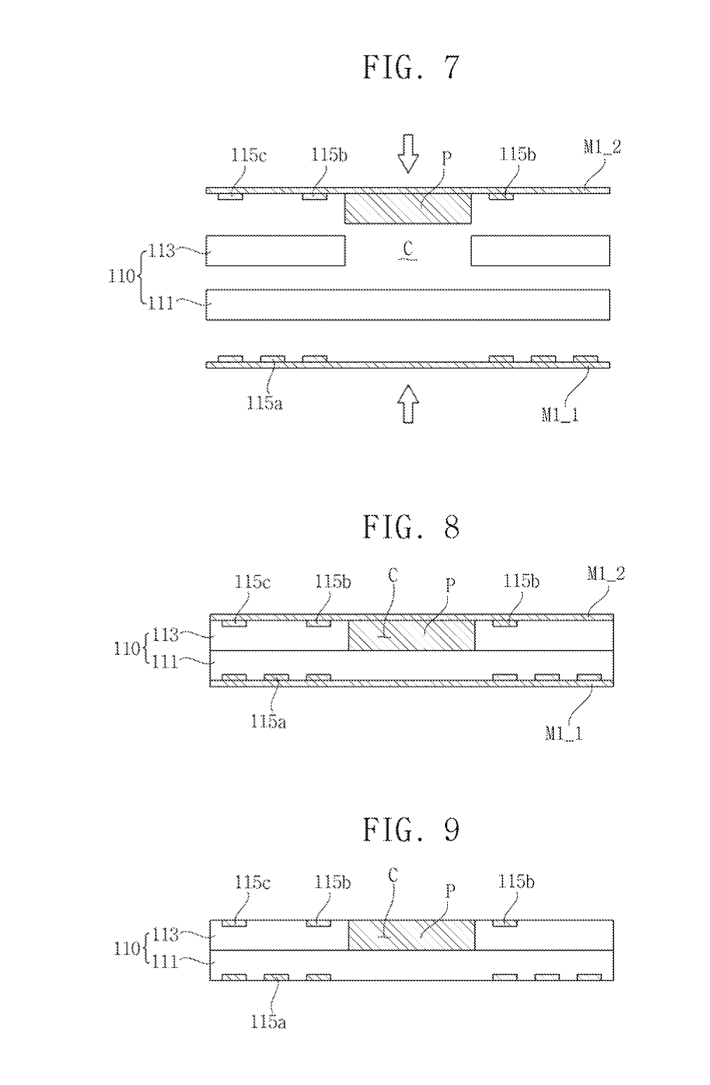

Referring to FIGS. 7 and 8, the method may include sequentially disposing a lower metal film M1_1 having one surface on which lower interconnections including first connection pads 115a are formed, a lower substrate 111, the upper substrate 113 including the cavity C, and an upper metal film M1_2 having one surface on which a protruding portion P corresponding to the cavity C and upper interconnections including second connection pads 115b and third connection pads 115c are formed, and forming a substrate structure including a package substrate 110 having the lower substrate 111 and the upper substrate 113, in which the lower metal film M1_1 and the upper metal film M1_2 are stacked respectively on a lower surface and an upper surface of the package substrate 110 by performing a hot-pressing process.

The lower substrate 111 may include a pre-preg.

Each of the lower metal film M1_1 and the upper metal film M1_2 may include Cu, Ni, or Al. The formation of the lower interconnections including the first connection pads 115a on the one surface of the lower metal film M1_1 may include forming a mask, in which portions corresponding to the lower interconnections are open on the one surface thereof, forming a cover mask on the other surface of the lower metal film M1_1, and then forming a plating layer on the open portions by performing an electroplating process.

Likewise, the formation of the protruding portion P and the upper interconnections including the second connection pads 115b and the third connection pads 115c on the one surface of the upper metal film M1_2 may include forming a mask, in which portions corresponding to the protruding portion P and the upper interconnections are open on the one surface of the upper metal film M1_2, forming a cover mask on the other surface of the upper metal film M1_2, and then forming a plating layer in the open portions by performing an electroplating process.

Here, the protruding portion P of the upper metal film M1_2 may have a shape corresponding to the cavity C of the upper substrate 113. For example, the protruding portion P may have a width, a length, and a thickness which may be appropriate dimensions to be inserted into the cavity C.

The disposition of the lower substrate 111, the upper substrate 113, the lower metal film M1_1, and the upper metal film M1_2 may include disposing the upper substrate 113 on the lower substrate 111, the lower metal film M1_1 under the lower substrate 111, and the upper metal film M1_2 on the upper substrate 113. The one surface of the lower metal film M1_1 may be opposite to the one surface of the upper metal film M1_2.

That is, the lower metal film M1_1 may be disposed under the lower substrate 111 so that the one surface thereof faces a lower surface of the lower substrate 11, and the upper metal film M1_2 may be disposed on the upper substrate 113 so that the one surface thereof faces an upper surface of the upper substrate 113. Here, the upper metal film M1_2 may be disposed on the upper substrate 113 so that the protruding portion P is aligned with the cavity C of the upper substrate 113.

According to the exemplary embodiment of the inventive concepts, since the cavity C is pre-formed by a cutting process, the upper substrate 113 may not be physically pressed and physically damaged during the hot-pressing process.

In addition, by using the upper metal film M1_2 having the protruding portion P corresponding to the cavity C of the upper substrate 113, shapes of an inner wall of the cavity C and an upper surface of the lower substrate 111 exposed in the cavity C may be maintained evenly, during the hot-pressing process. Accordingly, by maintaining the inner wall of the cavity C and the upper surface of the lower substrate 111 exposed in the cavity C to be even, the controller chip 120 may be stably disposed in the cavity C.

In addition, in the substrate structure, the lower interconnections including the first connection pads 115a may be buried in the lower substrate 111 adjacent to the lower surface of the lower substrate 111, and the upper interconnections including the second connection pads 115b and the third connection pads 115c may be buried in the upper substrate 113 adjacent to the upper surface of the upper substrate 113.

Referring to FIG. 9, the method may include removing the lower metal film M1_1 disposed on the lower surface of the lower substrate 111, and the upper metal film M1_2 disposed on the upper surface of the upper substrate 113 by performing an etching process. Accordingly, the lower interconnections including the first connection pads 115a may be exposed on the lower surface of the lower substrate 111, and the protruding portion P and the upper interconnections including the second connection pads 115b and the third connection pads 115c may be exposed on the upper surface of the upper substrate 113.

Referring to FIG. 10, the method may include removing the protruding portion P exposed on the upper surface of the upper substrate 113 by performing an etching process. The removal of the protruding portion P may further include forming a mask, in which a portion corresponding to the protruding portion P is open on the upper surface of the upper substrate 113, and forming a cover mask on the lower surface of the lower substrate 111. By removing the protruding portion P, the upper surface of the lower substrate 111 may be exposed in the cavity C of the upper substrate 113.

Referring to FIG. 11, the method may include forming a protection layer 119 on each of the lower surface of the lower substrate 111 and the upper surface of the upper substrate 113. The forming of the protection layer 119 may include forming an insulating material layer on each of the lower surface of the lower substrate 111 and the upper surface of the upper substrate 113, and selectively removing the insulating material layer to expose the first connection pads 115a, the second connection pads 115b, the third connection pads 115c, and the cavity C. Here, the insulating material layer may include film-type material and paste-type material. The protection layer 119 may include PSR.

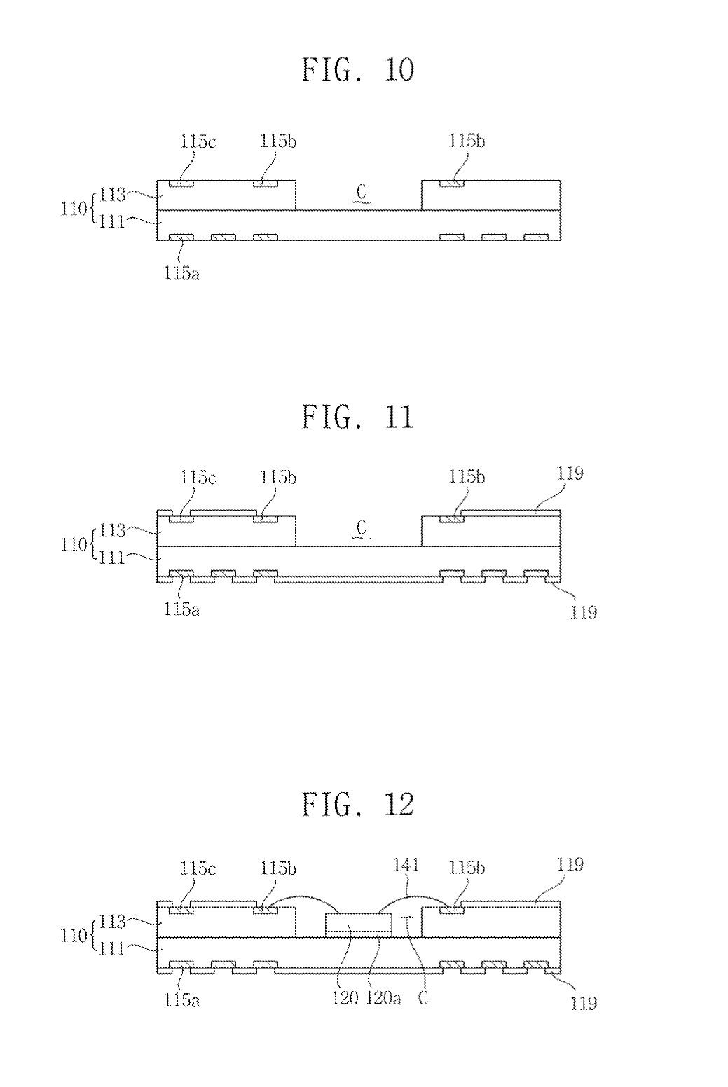

Referring to FIG. 12, the method may include disposing a controller chip 120 on the upper surface of the lower substrate 111 exposed in the cavity C of the upper substrate 113, and wire-bonding the controller chip 120 and the second connection pads 115b using first wires 141. The controller chip 120 may be attached onto the upper surface of the lower substrate 111 using a first adhesive layer 120a.

Referring to FIG. 13, the method may include disposing a chip stack 130 on the upper substrate 113, and wire-bonding the chip stack 130 and the third connection pads 115c using second wires 143. The chip stack 130 may include a plurality of memory chips 131, 132, 133, 134, 135, 136, 137, 138. The disposition of the chip stack 130 on the upper substrate 113 may include sequentially stacking the plurality of memory chips 131, 132, 133, 134, 135, 136, 137, 138 on the upper substrate 113. Here, the plurality of memory chips 131, 132, 133, 134, 135, 136, 137, 138 may be stacked in a cascade structure.

In addition, the plurality of memory chips 131, 132, 133, 134, 135, 136, 137, 138 may be fixed using second adhesive layers 130a. A lowermost second adhesive layer 130a disposed between a lowermost memory chip 131 and the upper substrate 113 may be relatively thicker than the other second adhesive layers 130a. Accordingly, the first wires 141 electrically connecting the controller chip 120 to the second connection pads 115b may be prevented from being in contact with the lowermost memory chip 131. Here, a portion of the first wires 141 may be buried in the lowermost second adhesive layer 130a disposed between the lowermost memory chip 131 and the upper substrate 113.

Next, referring back to FIG. 2A, the method may include forming a molding compound 150 which fills the cavity C and covers the chip stack 130 on the upper substrate 113. The molding compound 150 may include an EMC.

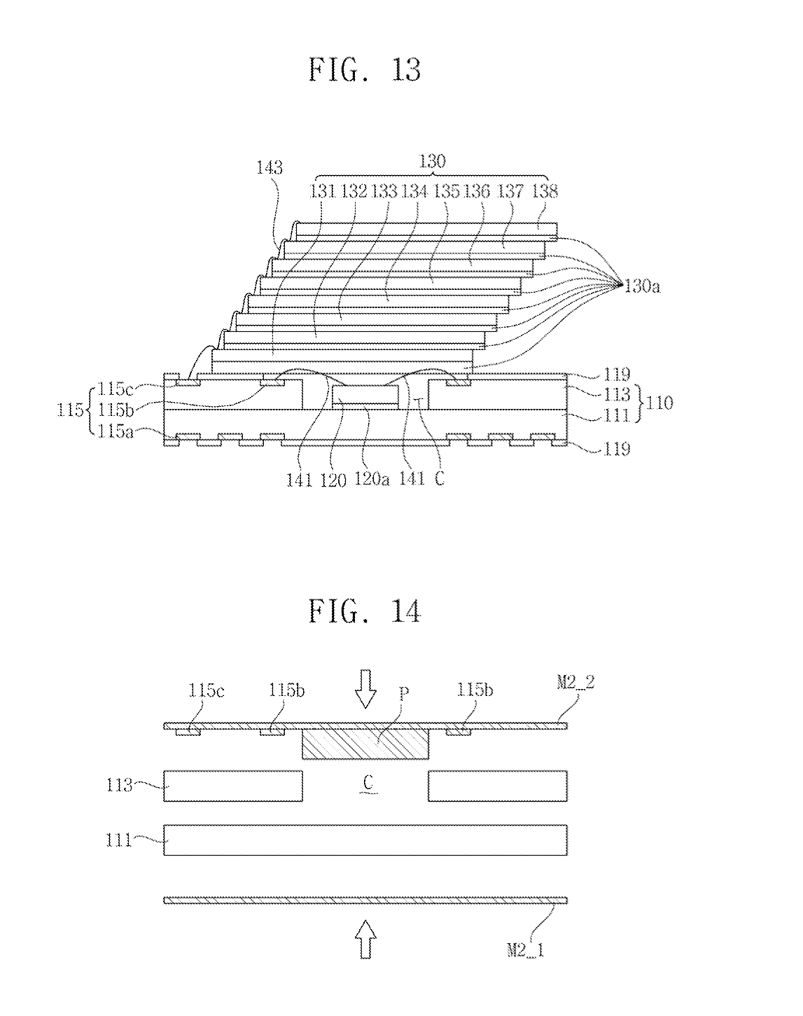

FIGS. 14 to 21 are views illustrating a method of fabricating a semiconductor package in accordance with an exemplary embodiment of the inventive concepts.

Referring to FIGS. 14 and 15, the method of fabricating a semiconductor package in accordance with the exemplary embodiment of the inventive concepts may include sequentially disposing a lower metal film M2_1, a lower substrate 111, an upper substrate 113 including a cavity C, and an upper metal film M2_2 having one surface on which a protruding portion P corresponding to the cavity C and upper interconnections including second connection pads 115b and third connection pads 115c are formed, and performing a hot-pressing process to form a substrate structure including a package substrate 110 having the lower substrate 111 and the upper substrate 113 and including the lower metal film M2_1 and the upper metal film M2_2 respectively formed on a lower surface and an upper surface of the package substrate 110.

Compared to FIGS. 7 and 8, in the present exemplary embodiment, lower interconnections including first connection pads 115a may not be formed on one surface of the lower metal film M2_1. Accordingly, the lower interconnections including the first connection pads 115a, which will be formed in a subsequent process, may protrude from a lower surface of the lower substrate 111 without being buried in the lower substrate 111. Since the formation of the cavity C in the upper substrate 113, and the formation of the protruding portion P and the upper interconnections on the one surface of the upper metal film M2_2 have been described above in detail, descriptions thereof are omitted herein.

Referring to FIG. 16, the method may include removing the upper metal film M2_2 by performing an etching process. The removing of the upper metal film M2_2 may further include forming a cover mask on the lower metal film M2_1 disposed on the lower surface of the lower substrate 111. Accordingly, only the upper metal film M2_2 may be removed and the lower metal film M2_1 may remain. In addition, since the upper metal film M2_2 is removed, upper surfaces of the upper interconnections including the second connection pads 115b and the third connection pads 115c and a upper surface of the protruding portion P may be exposed.

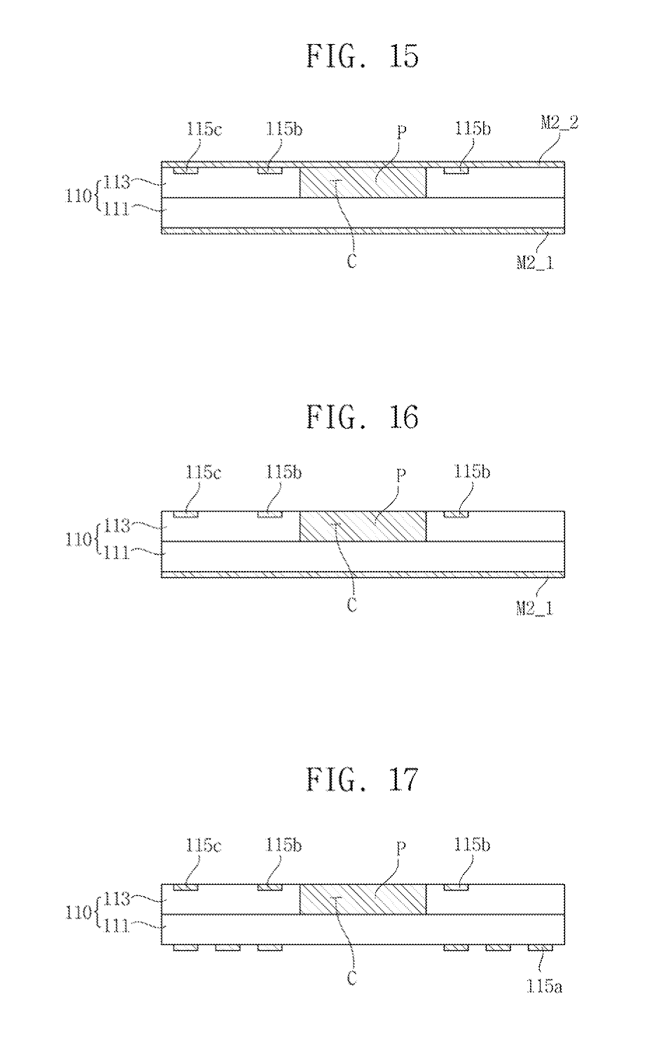

Referring to FIG. 17, the method may include forming lower interconnections including first connection pads 115a on the lower surface of the lower substrate 111. The forming of the lower interconnections may include forming a mask, in which portions other than portions corresponding to the lower interconnections are open on the lower surface of the lower substrate 111, forming a cover mask on an upper surface of the upper substrate 113, and selectively removing the lower metal film M2_1 by performing an etching process. Accordingly, the lower interconnections including the first connection pads 115a may protrude from the lower surface of the lower substrate 111 without being buried in the lower substrate 111.

Referring to FIG. 18, the method may include removing the protruding portion P exposed on upper surface of the upper substrate 113 by performing an etching process. By removing the protruding portion P, an upper surface of the lower substrate 111 may be exposed in the cavity C of the upper substrate 113.

Referring to FIG. 19, the method may include forming protection layers 119 exposing the first connection pads 115a, the second connection pads 115b, the third connection pads 115c, and the cavity C on the lower surface of the lower substrate 111 and the upper surface of the upper substrate 113.

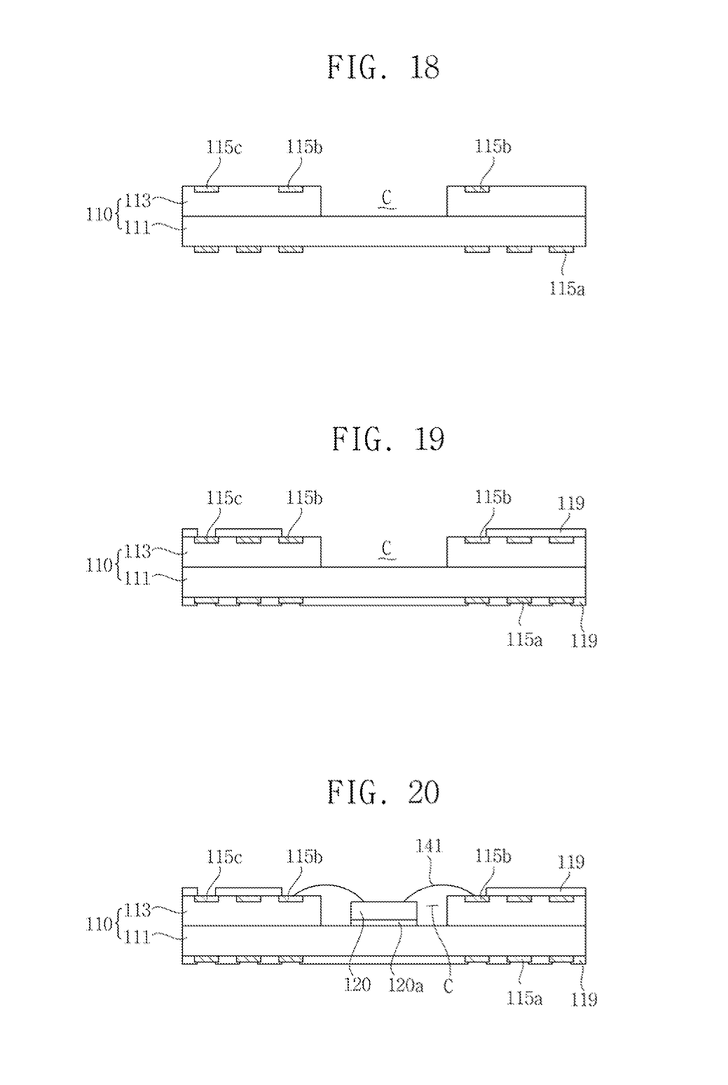

Referring to FIG. 20, the method may include disposing a controller chip 120 on the upper surface of the lower substrate 111 exposed in the cavity C of the upper substrate 113, and wire-bonding the controller chip 120 and the second connection pads 115b using first wires 141.

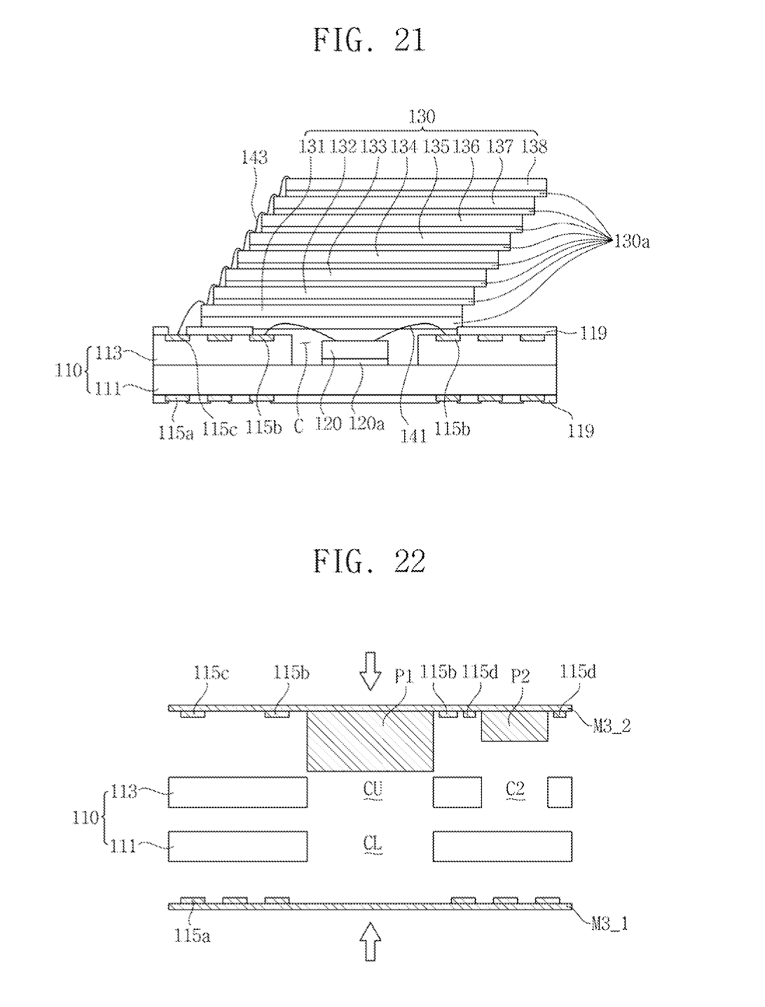

Referring to FIG. 21, the method may include disposing a chip stack 130 on the upper substrate 113, and wire-bonding the chip stack 130 to the third connection pads 115c using second wires 143.

Next, referring back to FIG. 2B, the method may include forming a molding compound 150 which fills the cavity C and covers the chip stack 130 on the upper substrate 113.

FIGS. 22 to 28 are view illustrating a method of fabricating a semiconductor package in accordance with an exemplary embodiment of the inventive concepts.

Referring to FIGS. 22 and 23, the method of fabricating a semiconductor package in accordance with the exemplary embodiment of the inventive concepts may include sequentially disposing a lower metal film M3_1 having one surface on which lower interconnections including first connection pads 115a are formed, a lower substrate 111 including a lower cavity CL, an upper substrate 113 in which an upper cavity CU overlaps the lower cavity CL and a second cavity C2 spaced apart from the upper cavity CU are formed, and an upper metal film M3_2 having one surface on which a first protruding portion P1 corresponding to the lower cavity CL and the upper cavity CU, a second protruding portion P2 corresponding to the second cavity C2, and upper interconnections including second connection pads 115b, third connection pads 115c, and fourth connection pads 115d are formed, and performing a hot-pressing process to form a substrate structure including the package substrate 110 including the lower substrate 111 and the upper substrate 113, and the lower metal film M3_1 and the upper metal film M3_2 respectively laminated on a lower surface and an upper surface of the package substrate 110.

The first protruding portion P1 may be inserted into the upper cavity CU and the lower cavity CL.

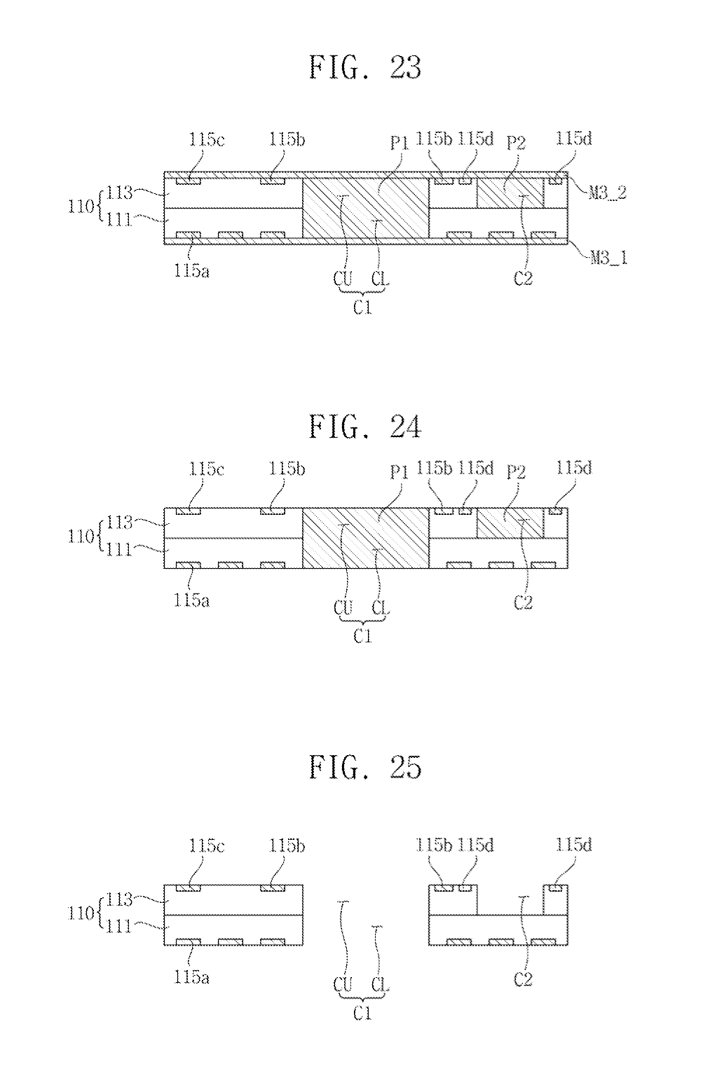

Referring to FIG. 24, the method may include removing the lower metal film M3_1 disposed on a lower surface of the lower substrate 111 and the upper metal film M3_2 disposed on an upper surface of the upper substrate 113 by performing an etching process. Accordingly, lower surfaces of the lower interconnections including the first connection pads 115a and a lower surface of the first protruding portion P1 may be exposed on the lower surface of the lower substrate 111, and upper surfaces of the upper interconnections including the second connection pads 115b, the third connection pads 115c, and the fourth connection pads 115d, an upper surface of the first protruding portion P1, and an upper surface of the second protruding portion P2 may be exposed on the upper surface of the upper substrate 113.

Referring to FIG. 25, the method may include removing the exposed first and second protruding portions P1, P2 by performing an etching process. The removing of the first protruding portion P1 and the second protruding portion P2 may include forming a mask, in which portions corresponding to the first protruding portion P1 and the second protruding portion P2 are open on the upper surface of the upper substrate 113, and further forming a mask, in which a portion corresponding to the first protruding portion P1 is open on the lower surface of the lower substrate 111.

Accordingly, a first cavity C1 including the upper cavity CU and the lower cavity CL may pass through from the upper surface of the upper substrate 113 to the lower surface of the lower substrate 111 by removing the first protruding portion P1, and a upper surface of the lower substrate 111 may be exposed in the second cavity C2 of the upper substrate 113 by removing the second protruding portion P2.

Referring to FIG. 26, the method may include forming a protection layer 119 on each of the lower surface of the lower substrate 111 and the upper surface of the upper substrate 113. The forming of the protection layer 119 may include forming an insulating material layer on the lower surface of the lower substrate 111 and the upper surface of the upper substrate 113, selectively removing the insulating material layer formed on the lower surface of the lower substrate 111 to expose the first connection pads 115a, and selectively removing the insulating material layer formed on the upper surface of the upper substrate 113 to expose the second connection pads 115b, the third connection pads 115c, the fourth connection pads 115d, the first cavity C1, and the second cavity C2. Accordingly, the protection layer 119 formed on the lower surface of the lower substrate 111 may be exposed by the lower cavity CL of the first cavity C1.

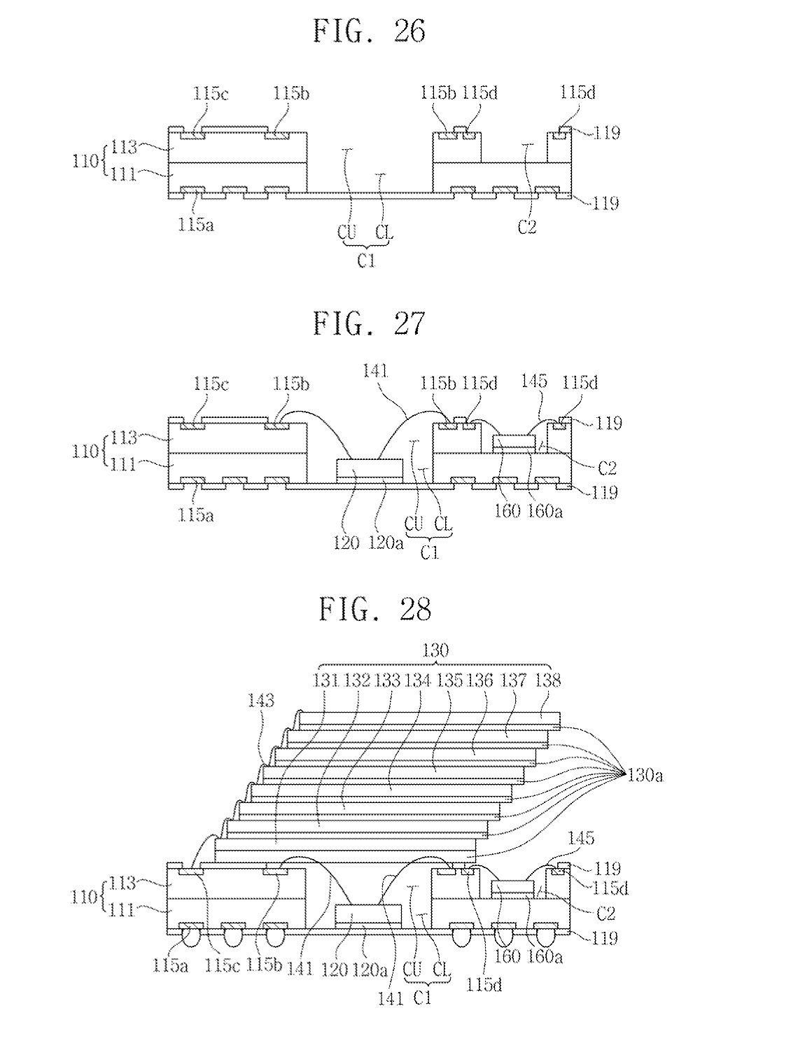

Referring to FIG. 27, the method may include disposing a controller chip 120 on the protection layer 119 exposed by the first cavity C1 and a device 160 on the upper surface of the lower substrate 111 exposed by the second cavity C2, wire-bonding the controller chip 120 to the second connection pads 115b using first wires 141, and wire-bonding the device 160 to the fourth connection pads 115d using third wires 145.

Referring to FIG. 28, the method may include disposing a chip stack 130 on the upper substrate 113, and wire-bonding the chip stack 130 to the third connection pads 115c using second wires 143.

Next, referring back to FIG. 4B, the method may include forming a molding compound 150 which fills the first cavity C1 and the second cavity C2 and covers the chip stack 130 on the upper substrate 113.

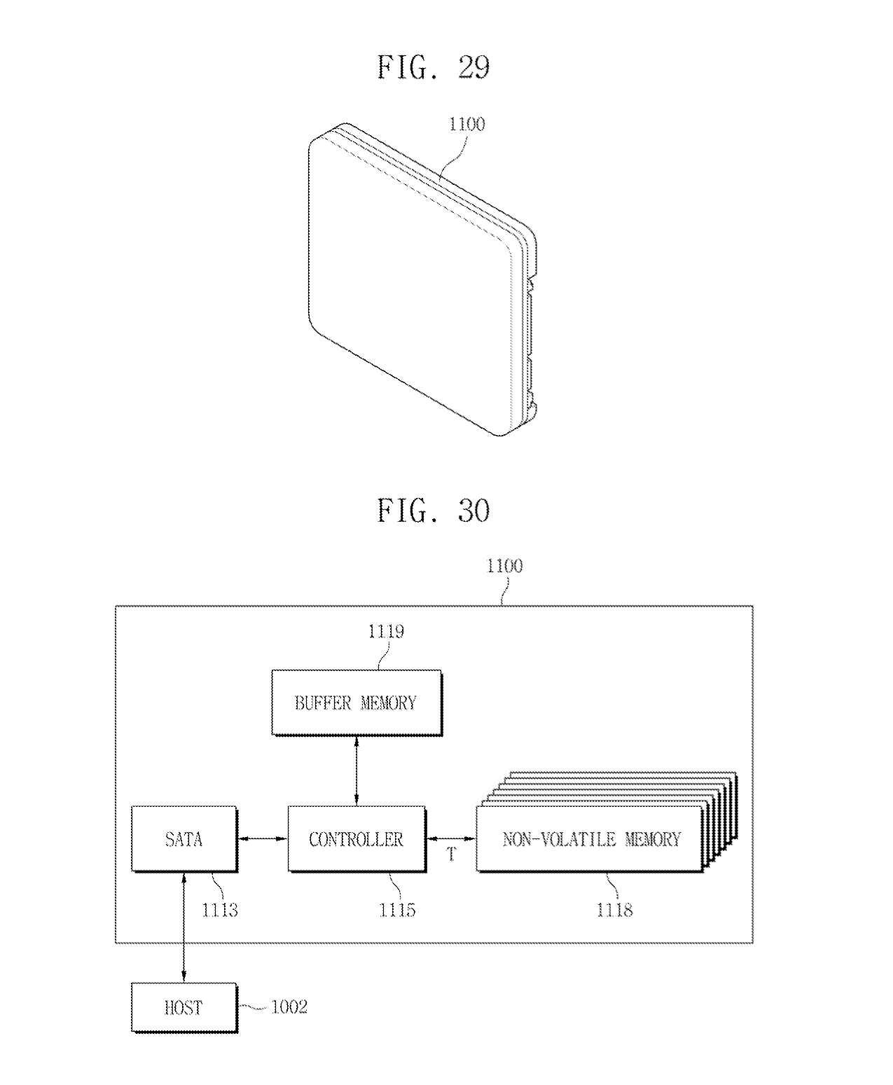

FIG. 29 is a perspective view illustrating an electronic device including at least one of the semiconductor packages in accordance with various exemplary embodiments of the inventive concepts, and FIG. 30 is a block diagram illustrating an electronic device including at least one of the semiconductor packages in accordance with various exemplary embodiments of the inventive concepts. Here, the electronic device may be a data storage device such as a solid state drive (SSD).

Referring to FIGS. 29 and 30, at least one of the semiconductor packages described with reference to FIGS. 1A to 4B in accordance with various exemplary embodiments of the inventive concepts may be applied to an SSD 1100. The SSD 1100 may include an interface 1113, a controller 1115, a non-volatile memory 1118, and a buffer memory 1119. The SSD 1100 may be an apparatus that stores information using semiconductor devices. The SSD 1100 is operationally faster, has a lower mechanical delay or failure rate, and generates less heat and noise than a hard disk drive (HDD). Further, the SSD 1100 may be smaller and lighter than the HDD. The SSD 1100 may be used in a laptop computer, a netbook, a desktop PC, an MP3 player, or a portable storage device.

The interface 1113 may be connected to a host 1002, and may transmit and receive electric signals, such as data. For example, the interface 1113 may be a device using a standard such as a Serial Advanced Technology Attachment (SATA), Integrated Drive Electronics (IDE), a Small Computer System Interface (SCSI), and/or a combination thereof. The non-volatile memory 1118 may be connected to the interface 1113 via the controller 1115. The non-volatile memory 1118 may function to store data received through the interface 1113.

The controller 1115 may be electrically connected to the interface 1113. The controller 1115 may be a microprocessor including a memory controller and a buffer controller.

The non-volatile memory 1118 may be electrically connected to the controller 1115. A data storage capacity of the SSD 1100 may correspond to the capacity of the non-volatile memory 1118.

The buffer memory 1119 may be electrically connected to the controller 1115. The buffer memory 1119 may include a volatile memory. The volatile memory may be a dynamic random access memory (DRAM) and/or a static random access memory (SRAM). The buffer memory 1119 has a relatively faster operating speed than the non-volatile memory 1118. The buffer memory may function to temporarily store data.

The data processing speed of the interface 1113 may be relatively faster than the operating speed of the non-volatile memory 1118. The data received through the interface 1113 may be temporarily stored in the buffer memory 1119 via the controller 1115, and then permanently stored in the non-volatile memory 1118 according to the data write speed of the non-volatile memory 1118. Further, frequently used items of the data stored in the non-volatile memory 1118 may be pre-read and temporarily stored in the buffer memory 1119. That is, the buffer memory 1119 may function to increase an effective operating speed of the SSD 1100 and reduce an error rate.

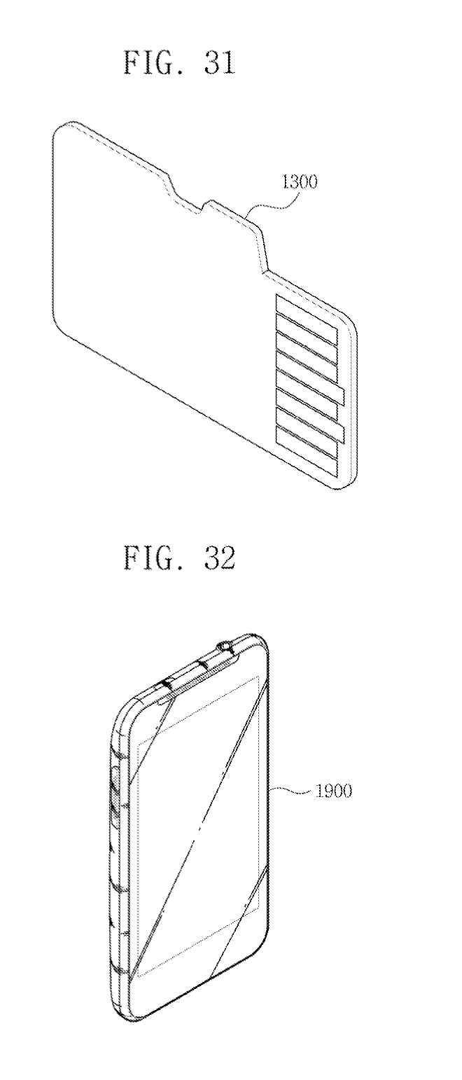

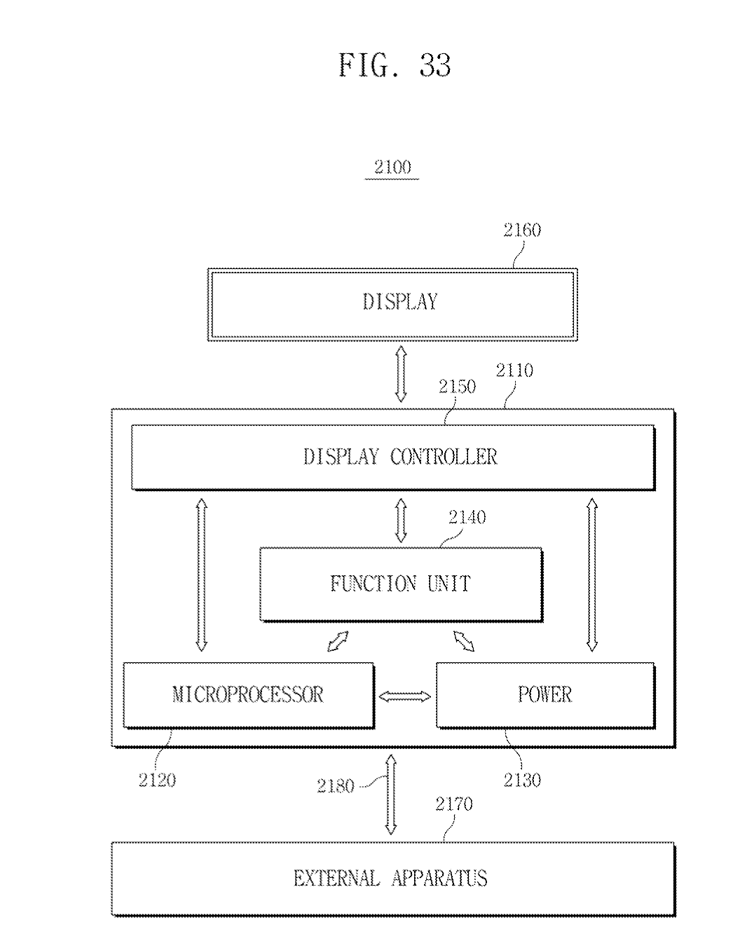

FIGS. 31 and 32 are perspective views of electronic devices having at least one of the semiconductor packages in accordance with various exemplary embodiments of the inventive concepts, and FIG. 33 is a block diagram of an electronic device having at least one of the semiconductor packages in accordance with various exemplary embodiments of the inventive concepts.

Referring to FIGS. 31 and 32, at least one of semiconductor packages in accordance with various exemplary embodiments described with reference to FIGS. 1A to 4B may be applied to a micro SD 1300 or a mobile wireless phone 1900. In addition, at least one of semiconductor packages in accordance with the various embodiments described with reference to FIGS. 1A to 4B may be usefully applied to electronic systems, such as a netbook, a laptop computer, or a tablet PC. For example, at least one of the semiconductor packages in accordance with the various embodiments described with reference to FIGS. 1A to 4B may be mounted on a mainboard in the mobile wireless phone 1900. In addition, at least one of the semiconductor packages in accordance with the various embodiments described with reference to FIGS. 1A to 4B may be provided to an expansion apparatus, such as the micro SD 1300, to be used combined with the mobile wireless phone 1900.

Referring to FIG. 33, at least one of the semiconductor packages in accordance with the various embodiments described with reference to FIGS. 1A to 4B may be applied to an electronic system 2100. The electronic system 2100 may include a body 2110 having a microprocessor unit 2120, a power unit 2130, a function unit 2140, and a display controller unit 2150. The body 2110 may be a motherboard formed of a printed circuit board (PCB). The microprocessor unit 2120, the power unit 2130, the function unit 2140, and the display controller unit 2150 may be installed on the body 2110. A display unit 2160 may be disposed inside or outside of the body 2110. For example, the display unit 2160 may be disposed on a surface of the body 2110 and display an image processed by the display controller unit 2150.

The power unit 2130 may receive a constant voltage from an external battery (not shown), and the like, and divide the voltage into various levels, and supply those voltages to the microprocessor unit 2120, the function unit 2140, and the display controller unit 2150, and the like. The microprocessor unit 2120 may receive a voltage from the power unit 2130 to control the function unit 2140 and the display unit 2160. The function unit 2140 may perform various functions of the electronic system 2100. For example, when the electronic system 2100 is a mobile phone, the function unit 2140 may have several components which perform functions of the mobile phone such as output of an image to the display unit 2160 or output of a voice to a speaker, by dialing or communication with an external apparatus 2170. When a camera is installed, the function unit 2140 may function as a camera image processor.

In an exemplary embodiment to which the inventive concepts are applied, when the electronic system 2100 is connected to a memory card, and the like, in order to expand a capacity thereof, the function unit 2140 may be a memory card controller. The function unit 2140 may exchange signals with the external apparatus 2170 through a wired or wireless communication unit 2180. In addition, when the electronic system 2100 needs a Universal Serial Bus (USB), and the like, in order to expand functionality, the function unit 2140 may function as an interface controller. Further, the function unit 2140 may include a mass storage apparatus.

At least one of the semiconductor packages in accordance with the various embodiments described with reference to FIGS. 1A to 4B may be applied to the function unit 2140 or the microprocessor unit 2120. For example, the function unit 2140 may include the package substrate 110, the controller chip 120 installed in the package substrate 110, and the memory chips 131, 132, 133, 134, 135, 136, 137, 138 disposed on the package substrate 110.

According to the various embodiments of the inventive concepts, since a controller chip configured to increase a data input/output speed of each of a plurality of memory chips is embedded in a package substrate of a semiconductor package, the data input/output speed of each memory chip can be increased, while a size of the semiconductor package is reduced.

In addition, as described above, since the controller chip is embedded in the package substrate, the number of stacked memory chips can increase, and accordingly a data storage device having a large capacity can be achieved.

The foregoing is illustrative of exemplary embodiments and is not to be construed as limiting thereof. Although a few exemplary embodiments have been described, those skilled in the art will readily appreciate that many modifications are possible without materially departing from the novel teachings and advantages. Accordingly, all such modifications are intended to be included within the scope of the inventive concepts as defined in the claims.

What is claimed is:

1. A semiconductor package, comprising:
a package substrate comprising a lower substrate and an upper substrate disposed on the lower substrate, the package substrate having a first cavity;
a first semiconductor chip disposed in the first cavity; and
a chip stack disposed on the upper substrate and configured to partially overlie the first cavity.

2. The semiconductor package of claim 1, wherein the first cavity has a shape of a rectangle elongated in a direction in a top view.

3. The semiconductor package of claim 2, wherein a center portion of the first cavity is overlain by the chip stack and both edge portions of the first cavity in the direction are not overlain by the chip stack.

4. The semiconductor package of claim 1, wherein the upper substrate further comprises a second cavity spaced apart from the first cavity and overlain by the chip stack.

5. The semiconductor package of claim 4, wherein the chip stack comprises a plurality of memory chips stacked in a cascade structure.

6. The semiconductor package of claim 5, wherein the second cavity is not overlain by a lowermost memory chip of the chip stack.

7. The semiconductor package of claim 4,
further comprising a passive device disposed in the second cavity,
wherein the first semiconductor chip is a controller chip.

8. The semiconductor package of claim 1, further comprising:
first connection pads formed on a lower surface of the lower substrate;
second connection pads formed on an upper surface of the upper substrate and electrically connected to the first semiconductor chip; and
third connection pads formed on the upper surface of the upper substrate and electrically connected to the chip stack.

9. The semiconductor package of claim 8,
further comprising a first wire configured to electrically connect the first semiconductor chip to at least one of the second connection pads,
wherein a portion of the first wire is inserted in an adhesive layer disposed between the chip stack and the package substrate.

10. The semiconductor package of claim 1,
further comprising a molding compound formed on the package substrate and configured to cover the chip stack,
wherein the molding compound fills the first cavity.

11. A semiconductor package, comprising:
a package substrate comprising a lower substrate and a upper substrate disposed on the lower substrate, the package substrate having a first cavity and a second cavity;
a first semiconductor chip disposed in the first cavity;
a second semiconductor chip disposed in the second cavity; and
a chip stack disposed on the upper substrate and configured to overlie the first and second cavities.

12. The semiconductor package of claim 11,
wherein the chip stack comprises a plurality of memory chips stacked in a cascade structure, and
wherein a lowermost memory chip of the chip stack is configured to overlie the first cavity and not overlie the second cavity.

13. The semiconductor package of claim 11, further comprising:
a first connection pad formed on a lower surface of the lower substrate;
a second connection pad formed on a upper surface of the upper substrate and electrically connected to the first semiconductor chip;
a third connection pad formed on the upper surface of the upper substrate and electrically connected to the chip stack; and
a fourth connection pad formed on the upper surface of the upper substrate and electrically connected to the second semiconductor chip.

14. The semiconductor package of claim 13, further comprising:
a first wire configured to electrically connect the first semiconductor chip to the second connection pad;
a second wire configured to electrically connect the chip stack to the third connection pad; and
a third wire configured to electrically connect the second semiconductor chip to the fourth connection pad,
wherein a portion of the first wire is inserted in an adhesive layer disposed between the chip stack and the package substrate.

15. The semiconductor package of claim 14, wherein the second wire and the third wire are not inserted in the adhesive layer.

16. A semiconductor package, comprising:
a package substrate comprising a first cavity;
a first semiconductor chip disposed in the first cavity; and
a chip stack disposed on the package substrate,
wherein the chip stack is configured to overlie a center portion of the first cavity and not overlie an edge portion of the first cavity.

17. The semiconductor package of claim 16,
wherein the package substrate comprises a lower substrate and an upper substrate, and
wherein the first cavity comprises a lower cavity configured to pass through the lower substrate and an upper cavity configured to pass through the upper substrate.

18. The semiconductor package of claim 17, wherein a sidewall of the lower cavity is vertically aligned with a sidewall of the upper cavity.

19. The semiconductor package of claim 17, further comprising:
a second cavity configured to pass through the upper substrate to expose a surface of the lower substrate; and
a second semiconductor chip disposed in the second cavity.

20. The semiconductor package of claim 19,
wherein the chip stack comprises s a plurality of memory chips stacked in a cascade structure, and
wherein a lowermost memory chip of the memory chip is configured to overlie the first semiconductor chip and not overlie the second semiconductor chip.
